(19) United States
(12) Patent Application Publication
(10) Pub. No.: US 2024/0388062 A1
(43) Pub. Date: Nov. 21, 2024

(54) HIGH-BANDWIDTH LASER WITH BALANCED INTRINSIC RESPONSE AND PARASITIC RESPONSE

(71) Applicant: Mellanox Technologies, Ltd., Yokneam (IL)

(72) Inventors: Itshak Kalifa, Batyam (IL); Elad Mentovich, Tel Aviv (IL); Matan Galanty, Korazim (IL)

(21) Appl. No.: 18/198,401

(22) Filed: May 17, 2023

(51) Int. Cl. H01S 5/183

(52) U.S. Cl. CPC H01S 5/18361

(57) ABSTRACT

High-bandwidth lasers having a balanced intrinsic response and parasitic response are described herein. For example, the present invention may be directed to a laser having an optimized parasitic transfer function and for which the bandwidth of the intrinsic response of the laser is increased by increasing a differential gain of the laser. The laser may balance increased bandwidth of the intrinsic transfer function due to increased cavity length with reduced bandwidth of the parasitic transfer function due to increased active resistance. For example, embodiments of the present invention may be directed to a laser configured to operate at an operating wavelength selected to maximize the bandwidth of the total response of the laser.

### CROSS-REFERENCE TO RELATED APPLICATION

To supplement the present disclosure, this application incorporates herein by reference U.S. patent application Ser. No. ______ for a “High Bandwidth Laser Having Optimized Parasitic Transfer Function” filed concurrently herewith.

### FIELD OF THE INVENTION

The present invention relates to high-bandwidth lasers balancing intrinsic response and parasitic response.

### BACKGROUND

With demand for high-speed and high-volume data communication increasing, communications providers are increasingly adopting optics-based communication solutions. To meet these demands, high-speed transmitters are being developed.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a laser having a total response that includes a parasitic response and an intrinsic response. The laser may be configured to operate at an operating wavelength selected to maximize the total response of the laser. In some embodiments, the laser may include a cavity defining a cavity length, where the cavity length determines the operating wavelength of the laser. Additionally, or alternatively, a parasitic transfer function of the parasitic response may have a lower −3 dB frequency for a laser design including another cavity having a longer cavity length than the cavity length. In some embodiments, a parasitic transfer function of the parasitic response may have a higher −3 dB frequency for a laser design including another cavity having a shorter cavity length than the cavity length.

In some embodiments, an intrinsic transfer function of the intrinsic response may have a higher −3 dB frequency for a laser design configured to operate at a longer operating wavelength than the operating wavelength. Additionally, or alternatively, an intrinsic transfer function of the intrinsic response may have a lower −3 dB frequency for a laser design configured to operate at a longer operating wavelength than the operating wavelength.

In some embodiments, the laser may have an active resistance and an active capacitance, and where one or more dopant densities in the laser are selected to optimize a parasitic transfer function of the parasitic response of the laser by (i) decreasing the active resistance and (ii) decreasing the active capacitance.

In another aspect, the present invention is directed to a laser including a first mirror region, a second mirror region, and an active region positioned between the first mirror region and the second mirror region. The active region may include a cavity defining a cavity length, and the cavity length may be a multiple of half an operating wavelength. The laser may have a total response including a parasitic response and an intrinsic response, and the laser may be configured to operate at the operating wavelength. The operating wavelength may be selected to maximize the total response of the laser.

In some embodiments, the first mirror region may include a first dopant at a first dopant density, and the second mirror region may include a second dopant at a second dopant density. The active region may have an active resistance, and the laser may have an active capacitance. The first dopant density and the second dopant density may be selected to optimize a parasitic transfer function of the parasitic response of the laser by (i) decreasing the active resistance of the active region and (ii) decreasing the active capacitance of the laser. In some embodiments, the first dopant density and the second dopant density may be selected to obtain an active resistance of between about 50 ohms and 70 ohms at an operating bias of the laser. Additionally, or alternatively, the active resistance may be less than about 90 ohms at an operating bias of the laser, and the active capacitance may be less than about 50 femtofarads at the operating bias of the laser.

In some embodiments, the first mirror region may have a first thickness and a first doping profile of a first dopant through the first thickness of the first mirror region. The second mirror region may have a second thickness and a second doping profile of a second dopant through the second thickness of the second mirror region. The first doping profile and the second doping profile may be selected to optimize a bandwidth at which the laser is capable of operating at the operating wavelength.

In some embodiments, the first mirror region may include a first distributed Bragg reflector, and the second mirror region may include a second distributed Bragg reflector.

In some embodiments, the active region may be undoped.

In some embodiments, the laser may include an aperture, and the active region may include a depleted junction under the aperture.

In some embodiments, the laser may be a vertical-cavity surface-emitting laser. For example, the laser may be an oxide confined vertical-cavity surface-emitting laser.

In some embodiments, the laser may be a light emitting diode, a top-emitting laser, a bottom-emitting laser, an edge-emitting laser, a GaAs-based laser, an InP-based laser, a directly modulated laser, a distributed-feedback laser, a lithographic vertical-cavity surface-emitting laser, a tunnel junction vertical-cavity surface-emitting laser, an oxide-free vertical-cavity surface-emitting laser, and/or the like.

In yet another aspect, the present invention is directed to a method of manufacturing a laser. The method may include determining an operating wavelength at which a predicted total response of the laser is maximized, where the predicted total response includes a predicted parasitic response of the laser and a predicted intrinsic response of the laser. The method may include manufacturing the laser to operate at the determined operating wavelength.

In some embodiments, manufacturing the laser may include providing a cavity defining a cavity length, where the cavity length is half the determined operating wavelength.

In some embodiments, determining the operating wavelength at which the predicted total response of the laser is maximized may include determining a parasitic −3 dB frequency of a predicted parasitic transfer function of the predicted parasitic response at a plurality of wavelengths, determining an intrinsic −3 dB frequency of a predicted intrinsic transfer function of the predicted intrinsic response at the plurality of wavelengths, and/or selecting, as the operating wavelength and from the plurality of wavelengths, a wavelength at which a combination of the parasitic −3 dB frequency and the intrinsic −3 dB frequency at the wavelength is greatest.

In some embodiments, manufacturing the laser may include selecting one or more dopant densities in the laser to optimize a predicted parasitic transfer function of the predicted parasitic response of the laser by (i) decreasing an active resistance of the laser and (ii) decreasing an active capacitance of the laser and/or doping portions of the laser to achieve the one or more dopant densities.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made to the accompanying drawings, wherein:

FIG. 1 illustrates a schematic cross-section of an example layer structure of an example laser, in accordance with an embodiment of the invention;

FIG. 2 illustrates a close-up view of the schematic cross-section of FIG. 1 with a superimposed equivalent electrical circuit model, in accordance with an embodiment of the invention;

FIG. 3 is a graph illustrating intrinsic, parasitic, and total transfer functions at 850 nanometers for two lasers, in accordance with an embodiment of the invention;

FIG. 4 is a graph illustrating intrinsic, parasitic, and transfer functions at 980 nanometers for two lasers, in accordance with an embodiment of the invention;

FIG. 5A is a graph illustrating the resistance of lasers having various doping levels in mirror regions as a function of current, in accordance with embodiments of the invention;

FIG. 5B is a graph illustrating the junction capacitance of lasers having various doping levels in mirror regions as a function of current, in accordance with embodiments of the invention;

FIG. 5C is a graph illustrating the operating voltage and the optical power of lasers having various doping levels in mirror regions as a function of current, in accordance with embodiments of the invention;

FIG. 5D is a close-up view of the dashed box of the graph of FIG. 5C;

FIG. 6A is a density map illustrating the junction capacitance minimum values of lasers having various doping levels in mirror regions, in accordance with embodiments of the invention;

FIG. 6B is a density map illustrating the current at which the junction capacitance minimum values of the lasers of FIG. 6A occur, in accordance with embodiments of the invention;

FIG. 6C is a density map illustrating the resistance of lasers having various doping levels in mirror regions, in accordance with embodiments of the invention;

FIG. 6D is a density map illustrating the active capacitance of lasers having various doping levels in mirror regions, in accordance with embodiments of the invention;

FIG. 6E is a density map illustrating the −3 dB frequency of parasitic transfer functions at an operating current of lasers having various doping levels in mirror regions, in accordance with embodiments of the invention;

FIGS. 7A-7D are density maps illustrating the −3 dB frequency of parasitic transfer functions at different operating currents of lasers having various doping levels in mirror regions, in accordance with embodiments of the invention;

FIG. 8 illustrates a method for manufacturing a laser, in accordance with an embodiment of the invention;

FIG. 9 illustrates another method for manufacturing a laser, in accordance with an embodiment of the invention;

FIG. 10 is a graph illustrating the intrinsic and parasitic −3 dB frequencies of three lasers as a function of operating wavelength, in accordance with an embodiment of the invention;

FIG. 11 illustrates another method for manufacturing a laser, in accordance with an embodiment of the invention; and

FIG. 12 illustrates another method for manufacturing a laser, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). As used herein, terms such as “top,” “about,” “around,” and/or the like are used for explanatory purposes in the examples provided below to describe the relative position of components or portions of components. As used herein, the terms “substantially” and “approximately” refer to tolerances within manufacturing and/or engineering standards. Like numbers refer to like elements throughout. No element, act, or instruction used herein should be construed as critical or essential unless explicitly described as such.

As noted, demand for high-speed and high-volume data communication is increasing, and communications providers are increasingly adopting optics-based communication solutions. To meet these demands, high-speed transmitters are being developed. Such high-speed transmitters may include different types of lasers, such as light emitting diodes, top-emitting lasers, bottom-emitting lasers, edge-emitting lasers, GaAs-based lasers, InP-based lasers, directly modulated lasers, distributed-feedback lasers, lithographic VCSELs, tunnel junction VCSELs, oxide-free VCSELs, and/or the like. Lasers for broad-band high-speed transmission may be designed to achieve a highest possible transmission bandwidth, which may correspond to a frequency at which a transfer function of the laser's response drops 3 decibels (dB) below its low-frequency power (e.g., the −3 dB frequency of the response). When designing a laser, characteristics of the laser are selected to optimize the bandwidth of an intrinsic response of the laser at a transmission wavelength, where the intrinsic response may be characterized by an intrinsic transfer function. However, a total response of the laser (e.g., an actual response corresponding to the laser's transmission capabilities characterized by a total transfer function) includes not only the intrinsic transfer function but also a parasitic response characterized by a transfer function. The parasitic response and transfer function may vary depending on the device structure, the structure layout, configuration, materials, and more. In most cases, it is desirable to minimize the parasitic effect, thus increasing the parasitic transfer function bandwidth, so that the total bandwidth can be increased.

However, some lasers may be designed to have an optimized parasitic transfer function. For example, an optimized parasitic transfer function may be achieved in directly modulated lasers, such as VCSELs and, in particular, oxide-confined VCSELs, by decreasing the active resistance of the laser's active region and decreasing the active capacitance of the laser because the active resistance and the active capacitance are the most influential parameters on the transfer function of the parasitic response. In some embodiments, the laser may include an active region having an active resistance as well as another region (e.g., one or more mirror regions, an n-type distributed Bragg reflector (DBR), a p-type DBR, and/or the like), where the other region has a dopant density that decreases the active resistance of the active region and decreases the active capacitance of the laser. By decreasing the active resistance and the active capacitance, the parasitic transfer function of the laser is enhanced, and the parasitic response of the laser is minimized. In particular, the parasitic transfer function of the laser has a higher −3 dB frequency at the laser's operating wavelength as compared to a laser without such an enhanced and/or optimized parasitic transfer function. By increasing the −3 dB frequency of the parasitic transfer function, the total transfer function of the laser (e.g., a combination of the intrinsic transfer function and the parasitic transfer function) has a higher −3 dB frequency at the laser's operating wavelength, thereby allowing the laser to operate at higher baud rates and/or data rates. In some embodiments, doping profiles of the other regions may be configured to improve the parasitic transfer function of the laser, and the dopant densities of the other regions may be manipulated to improve the parasitic transfer function of the laser. For example, a vertical-cavity surface-emitting laser (VCSEL) may include first and second mirror regions, where the dopant densities in at least portions of the first and second mirror regions are selected to optimize the parasitic transfer function of the VCSEL by decreasing the active resistance and the active capacitance of the VCSEL. Although the foregoing example generally describes an oxide confined VCSEL, a similar approach may be used to enhance the parasitic transfer function of other types of lasers, improve the total response of the laser, and permit the laser to operate at higher bandwidths. For example, in other types of lasers, the parasitic transfer function may be enhanced and/or optimized by reducing a junction capacitance, which is a component of the active capacitance.

However, even for lasers with such an optimized parasitic transfer function, the total responses of the lasers may not have high enough bandwidths to meet the demands for high-speed and high-volume data communication. Accordingly, embodiments of the present invention may enhance both the intrinsic response and the parasitic response simultaneously to achieve the highest total response. For example, some embodiments of the present invention are directed to a laser having an optimized parasitic transfer function and for which the bandwidth of the intrinsic transfer function of the laser is increased by increasing a differential gain of the laser. Increasing the differential gain may be achieved by increasing strain in the active region of the laser, which shifts peak gain of the laser to lower energy levels corresponding to longer operating wavelengths. Such a shift increases the bandwidth of the intrinsic transfer function but also requires an increase in cavity length in the active region, which increases the active resistance of the laser. Increasing the active resistance of the laser reduces the bandwidth of the parasitic transfer function of the laser, which reduces the bandwidth of the total response of the laser. Thus, some embodiments of the present invention are directed to a laser that balances increased bandwidth of the intrinsic transfer function due to increased cavity length with reduced bandwidth of the parasitic transfer function due to increased active resistance. For example, embodiments of the present invention are directed to a laser configured to operate at an operating wavelength selected to maximize the bandwidth of the total response of the laser (e.g., an actual response corresponding to the laser's transmission capabilities characterized by a total transfer function).

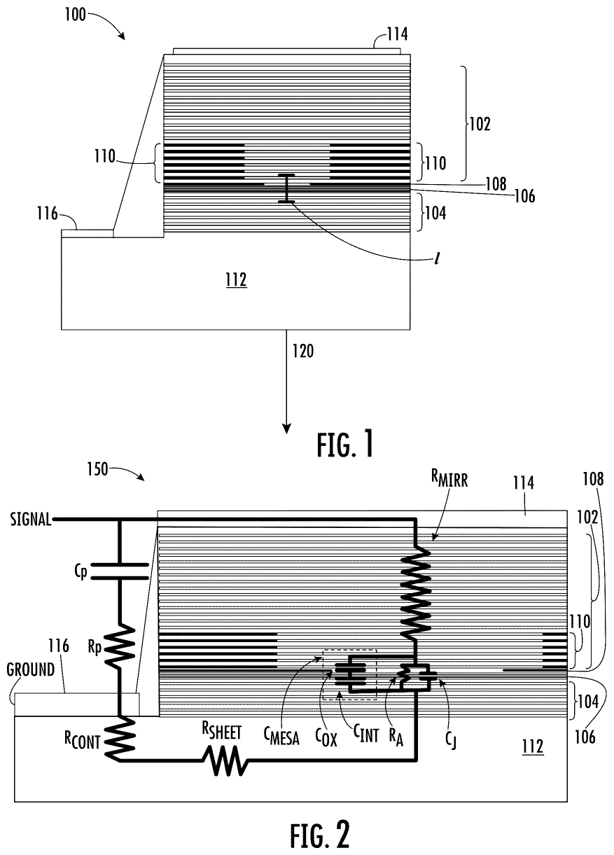

FIG. 1 illustrates a schematic cross-section of an example layer structure of a laser 100, in accordance with an embodiment of the invention. In particular, the cross-section of FIG. 1 is taken in a plane that is substantially parallel to an emission axis 120 of the laser 100. As shown in FIG. 1, the laser 100 may include a first mirror region 102, a second mirror region 104, an active region 106, an oxide aperture 108, oxidation layers 110, a substrate 112, a first contact 114, and a second contact 116.

In some embodiments, the first mirror region 102 may include a p-type mirror, and the second mirror region 104 may include an n-type mirror. For example, the first mirror region 102 may include a p-type distributed Bragg reflector (DBR), and the second mirror region 104 may include an n-type DBR. In such an example, the first contact 114 may include a p-contact, and the second contact 116 may include an n-contact. In some embodiments, each of the first mirror region 102 and the second mirror region 104 may include a dopant having a doping profile through a thickness of the respective region (e.g., in a horizontal and/or a vertical direction in the orientation shown in FIG. 1).

As shown in FIG. 1, the active region 106 may be positioned between the first mirror region 102 and the second mirror region 104. The active region 106 may include one or more quantum wells for light generation. As also shown in FIG. 1, the active region 106 may be under the oxide aperture 108. For example, the active region 106 may include a depleted junction under the oxide aperture 108. In some embodiments, the active region 106 may be intrinsic, undoped, and/or the like. Additionally, or alternatively, the laser 100 may include one or more oxide apertures in addition to the oxide aperture 108.

In some embodiments, and as shown in FIG. 1, the oxidation layers 110 may be formed in the first mirror region 102, such that the laser 100 is an oxide-confined laser. In this regard, the oxidation layers 110 may shape the oxide aperture 108 and encapsulate the active region 106 to reduce a threshold current of the laser 100 and improve a quantum efficiency of the laser 100.

As shown in FIG. 1, the first mirror region 102, the second mirror region 104, the active region 106, the oxide aperture 108, the oxidation layers 110, the first contact 114, and the second contact 116 may be positioned above a surface of the substrate 112. For example, the second mirror region 104 may be deposited on the substrate 112, the active region 106 may be disposed on the second mirror region 104, and the first mirror region 102 may be deposited on the active region 106. In some embodiments, the oxidation layers 110 and the oxide aperture 108 may be formed in the first mirror region 102. The first contact 114 may be formed on a surface of the first mirror region 102 opposite the active region 106, and the second contact 116 may be formed on the surface of the substrate 112 such that the second contact 116 is electrically isolated from the other components on the surface of the substrate 112.

As will be appreciated by one of ordinary skill in the art in light of this disclosure, the laser 100 may include other elements, such as metal contacts, one or more trenches, one or more coatings (e.g., an anti-reflective coating and/or the like), one or more insulators, one or more lenses, and/or the like. Although the laser 100 depicted in FIG. 1 is a bottom-emitting VCSEL, other embodiments in accordance with the present invention may include light emitting diodes, top-emitting lasers, bottom-emitting lasers, edge-emitting lasers, GaAs-based lasers, InP-based lasers, directly modulated lasers, distributed-feedback lasers, lithographic VCSELs, tunnel junction VCSELs, oxide-free VCSELs, and/or the like

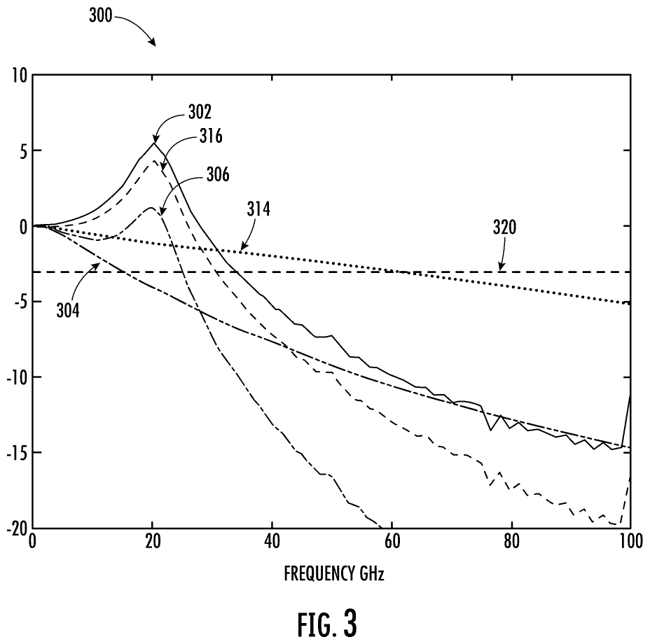

FIG. 2 illustrates a close-up view of the schematic cross-section of FIG. 1 with a superimposed equivalent electrical circuit model 150, in accordance with an embodiment of the invention. In particular, the electrical circuit model 150 includes the parasitic elements of the laser 100. Parasitic capacitance and resistance (Cₚ and Rₚ respectively) represent capacitance and dielectric losses between the signal and ground pads and depend on the geometrics and materials used on the first contact 114 and the second contact 116.

As shown in FIG. 2, the electrical circuit model 150 includes a mirror resistance Rₘᵢᵣᵣ representative of resistance associated with the first mirror region 102 and the second mirror region 104. A sheet resistance Rₛₕₑₑₜ may represent the sheet resistance in the second contact 116, and a contact resistance R_{cont} may represent the contact resistance for the first contact 114 and the second contact 116.

As also shown in FIG. 2, the electrical circuit model 150 includes a mesa capacitance Cₘₑₛₐ corresponding to an oxide capacitance Cₒₓ in series with an intrinsic capacitance Cᵢₙₜ associated with an intrinsic region below the oxide aperture 108 and may be associated with active region parameters, such as thickness, number of quantum wells, material composition, and/or the like. The oxide capacitance Cₒₓ may be associated with mesa diameter oxide aperture, number of oxide layers, thickness of the oxide layers, taper, and other parameters. A junction capacitance Cⱼ may represent a diode junction capacitance in an apertured area where current flows. The junction capacitance Cⱼ may be a sum of a depletion capacitance and a diffusion capacitance.

As also shown in FIG. 2, the electrical circuit model 150 includes an active resistance Rₐ. The active resistance Rₐ may be representative of resistance of the active region 106. In some embodiments, the active resistance Rₐ may be representative of junction resistance in the apertured area where current flows.

An active capacitance Cₐ of the laser 100 may include the junction capacitance Cⱼ in parallel to the mesa capacitance Cₘₑₛₐ. As previously noted, the mesa capacitance Cₘₑₛₐ corresponds to the oxide capacitance Cₒₓ in series with the intrinsic capacitance Cᵢₙₜ. Accordingly, the active capacitance Cₐ may be expressed using the following equation:

$${C}_{a} = {C}_{j} + {( \frac{1}{{C}_{ox}} + \frac{1}{{C}_{int}} )}^{- 1} .$$

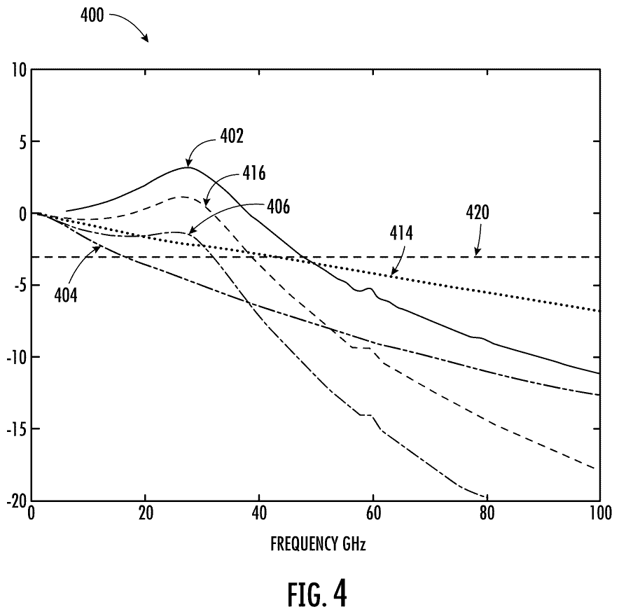

As previously noted, a total response of the laser (e.g., an actual response corresponding to the laser's transmission capabilities) includes not only an intrinsic response but also a parasitic response. In this regard, the electrical circuit model 150 may be used to evaluate the parasitic transfer function of the parasitic response of the laser 100. In particular, the most influential parameters on the parasitic transfer function are the active resistance Ra and the active capacitance Cₐ of the laser 100. Thus, some embodiments of the present invention enhance the parasitic transfer function of a laser by decreasing the active resistance Ra and the active capacitance Cₐ of the laser. In particular, and as will be described herein with respect to FIGS. 3-9, some embodiments of the present invention may include a laser having dopant profiles and/or densities in mirror regions that decrease the active resistance Ra and the active capacitance Cₐ of the laser.

FIG. 3 is a graph 300 illustrating intrinsic, parasitic, and total transfer functions at 850 nanometers for two lasers, one of which has a minimized parasitic response (e.g., an enhanced parasitic transfer function bandwidth) in accordance with an embodiment of the invention. The graph 300 of FIG. 3 also illustrates a −3 dB plot 320, which may be used to identify bandwidths of responses of the two lasers based on intersections of the transfer functions and the −3 dB plot 320. For a first laser that does not have an enhanced parasitic transfer function, the graph 300 illustrates an intrinsic transfer function 302, a parasitic transfer function 304, and a total transfer function 306. As can be seen in the graph 300, the intrinsic transfer function 302 has a bandwidth of about 34 GHz. Additionally, the parasitic transfer function 304 has a bandwidth of about 15 GHz. Finally, the total transfer function 306 of the first laser (e.g., the combination of the intrinsic transfer function 302 and the parasitic transfer function 304) has a bandwidth of about 25 GHz.

The graph 300 also illustrates a parasitic transfer function 314 and a total transfer function 316 of a second laser having the same intrinsic transfer function 302 as the first laser but also having an optimized parasitic transfer function in accordance with embodiments of the present invention. In particular, the parasitic transfer function 314 has a bandwidth of about 60 GHz, which is much higher than the 15 GHz bandwidth of the parasitic transfer function 304 of the first laser. Furthermore, the total transfer function 316 of the second laser (e.g., the combination of the intrinsic transfer function 302 and the parasitic transfer function 314) has a bandwidth of about 30 GHz. Thus, for the second laser having the optimized parasitic transfer function, the total transfer function 316 is limited by the intrinsic transfer function 302, rather than the parasitic transfer function 314, and is higher than the total transfer function 306 of the first laser.

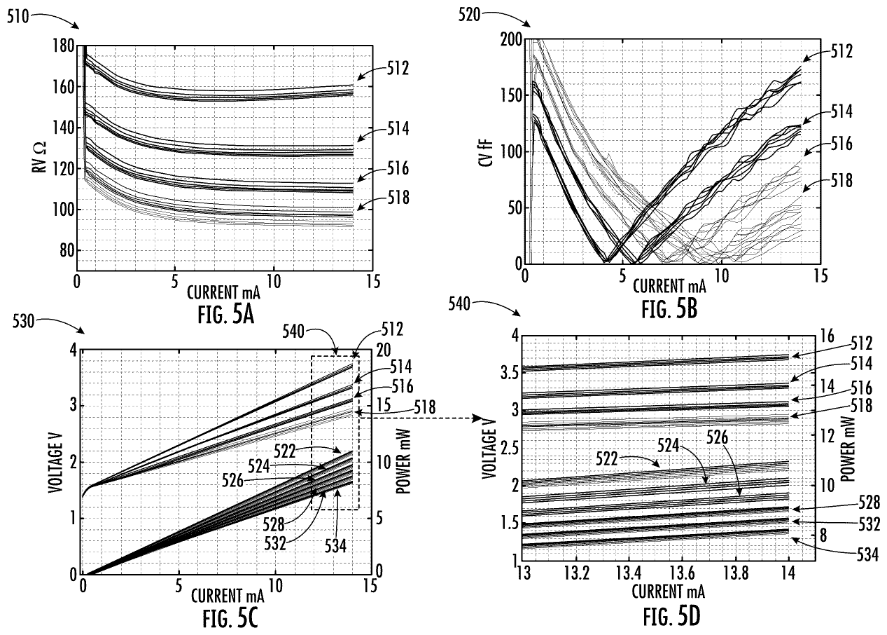

FIG. 4 is a graph 400 illustrating intrinsic, parasitic, and total transfer functions at 980 nanometers for two lasers, one of which has a minimized parasitic response (e.g., an enhanced parasitic transfer function bandwidth) in accordance with an embodiment of the invention. The graph 400 of FIG. 4 also illustrates a −3 dB plot 420, which may be used to identify bandwidths of responses of the two lasers based on intersections of the transfer functions and the −3 dB plot 420. For a first laser that does not have an enhanced parasitic transfer function, the graph 400 illustrates an intrinsic transfer function 402, a parasitic transfer function 404, and a total transfer function 406. As can be seen in the graph 400, the intrinsic transfer function 402 has a bandwidth of between about 45 GHz and 50 GHz. Additionally, the parasitic transfer function 404 has a bandwidth of less than 20 GHz. Finally, the total transfer function 406 of the first laser (e.g., the combination of the intrinsic transfer function 402 and the parasitic transfer function 404) has a bandwidth of between about 30 GHz and 40 GHz.

The graph 400 also illustrates a parasitic transfer function 414 and a total transfer function 416 of a second laser having the same intrinsic transfer function 402 as the first laser but also having an optimized parasitic transfer function in accordance with embodiments of the present invention. In particular, the parasitic transfer function 414 has a bandwidth of between about 40 GHz and 50 GHz, which is much higher than the sub −20 GHz bandwidth of the parasitic transfer function 404 of the first laser. Furthermore, the total transfer function 416 of the second laser (e.g., the combination of the intrinsic transfer function 402 and the parasitic transfer function 414) has a bandwidth of between about 35 GHz and 40 GHz. Thus, for the second laser having the optimized parasitic transfer function, the total transfer function 416 is limited by the parasitic transfer function 414 but is higher than the total transfer function 406 of the first laser.

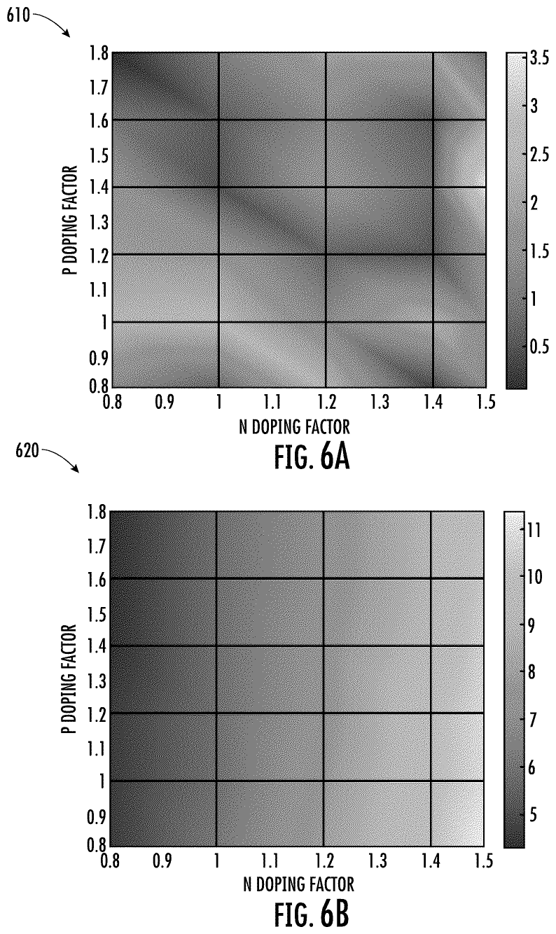

FIG. 5A is a graph 510 illustrating the resistance of lasers having various doping levels in mirror regions as a function of current, in accordance with embodiments of the invention. In particular, the lasers are VCSELs for emitting light having a wavelength of 980 nanometers and having an n-type doped mirror region and a p-type doped mirror region. As shown in FIG. 5A, the plotted lines generally fall into four distinct groups 512, 514, 516, and 518. In FIG. 5A, darker plot lines correspond to lasers having relatively lower average n-type doping levels and relatively lower average p-type doping levels in the mirror regions. The lighter plot lines correspond to lasers having relatively higher average n-type doping levels and relatively higher average p-type doping levels in the mirror regions. For example, the plot lines of group 512 correspond to lasers having the lowest average n-type doping levels and lowest average p-type doping levels, and the plot lines of group 518 correspond to lasers having the highest average n-type doping levels and highest average p-type doping levels.

For each laser within a given grouping shown in FIG. 5A, the laser has the same average n-type doping level as other lasers within its grouping, but the laser's average p-type doping level is different. For example, the highest plot line in group 512 and the lowest plot line in group 512 correspond to lasers having the same average n-type doping level but different average p-type doping levels. As demonstrated by the distinct groupings shown in FIG. 5A, the average n-type doping level appears to have the greatest impact on resistance, while the average p-type doping level has a smaller impact on the resistance. However, as shown by the difference between the highest plot line in group 518 and the lowest plot line in group 518, for lasers having higher average n-type doping levels, the average p-type doping level may have a greater impact on the resistance as compared to the impact of average p-type doping levels for lasers having lower average n-type doping levels, such as the lasers of group 512. Furthermore, the graph 510 of FIG. 5A demonstrates that higher average n-type doping levels and higher average p-type doping levels in the mirror regions of a laser may result in a lower resistance for the laser as compared to a resistance of a similar laser having lower average n-type doping levels and lower average p-type doping levels.

FIG. 5B is a graph 520 illustrating the junction capacitance of lasers having various doping levels in mirror regions as a function of current, in accordance with embodiments of the invention. The lasers and corresponding plot lines are the same lasers as those described with respect to FIG. 5A. As shown in FIG. 5B, the plotted lines generally fall into the same four distinct groups 512, 514, 516, and 518.

As demonstrated by the distinct groupings shown in FIG. 5B, the average n-type doping level also appears to have the greatest impact on junction capacitance, while the average p-type doping level has a smaller impact on the junction capacitance. However, as shown by the difference between the highest plot line in group 518 and the lowest plot line in group 518, for lasers having higher average n-type doping levels, the average p-type doping level may have a greater impact on the junction capacitance as compared to the impact of average p-type doping levels for lasers having lower average n-type doping levels, such as the lasers of group 512.

Furthermore, the graph 520 of FIG. 5B demonstrates that the junction capacitance minimum points depend on a chosen operating current. For example, for a laser with an operating current of approximately 7 milliamps, the optimized doping levels for minimal junction capacitance correspond to doping levels within group 516. As another example, for a laser with an operating current of approximately 10 milliamps, the optimized doping levels for minimal junction capacitance correspond to doping levels within group 518. Additionally, the graph 520 of FIG. 5B demonstrates that higher average n-type doping levels and higher average p-type doping levels in the mirror regions of a laser may result in a lower junction capacitance for the laser as compared to a junction capacitance of a similar laser having lower average n-type doping levels and lower average p-type doping levels.

FIG. 5C is a graph 530 illustrating the operating voltage and the optical power of lasers having various doping levels in mirror regions as a function of current, in accordance with embodiments of the invention. FIG. 5D is a close-up view 540 of the dashed box on the graph 530 of FIG. 5C. The lasers and corresponding plot lines of FIGS. 5C and 5D are the same lasers as those described with respect to FIGS. 5A and 5B. However, in FIGS. 5C and 5D, the upper set of plot lines including the four distinct groups 512, 514, 516, and 518 illustrate the operating voltage (as shown on the left, vertical axis) of the lasers as a function of current. The lower set of plot lines including the six distinct groups 522, 524, 526, 528, 532, and 534 illustrate the optical power (as shown on the right, vertical axis) of the lasers as a function of current.

With respect to operating voltage, the graph 530 of FIG. 5C and close-up view 540 of FIG. 5D demonstrate that higher average n-type doping levels and higher average p-type doping levels in the mirror regions of a laser may result in a lower operating voltage at a given current for the laser as compared to an operating voltage at the given current of a similar laser having lower average n-type doping levels and lower average p-type doping levels. Such a result is consistent with the correspondence between higher average doping levels and lower resistance demonstrated in the graph 510 of FIG. 5A.

With respect to optical power and as noted, the lower set of plot lines illustrating the optical power of the lasers includes six distinct groups 522, 524, 526, 528, 532, and 534. For each laser within a given grouping for optical power, the laser has the same average p-type doping level as other lasers within its grouping, but the laser's average n-type doping level is different. For example, the highest plot line in group 522 and the lowest plot line in group 522 correspond to lasers having the same average p-type doping level but different average n-type doping levels.

As demonstrated by the distinct groupings shown in FIGS. 5C and 5D, the average p-type doping level appears to have the greatest impact on optical power, while the average n-type doping level has a smaller impact on the optical power. Such an impact may be due to optical absorption caused by p-type doping. For example, the plot lines of group 522 correspond to lasers having the lowest average p-type doping levels, and the plot lines of group 534 correspond to lasers having the highest average p-type doping levels.

Accordingly, FIGS. 5A, 5B, 5C, and 5D demonstrate that increasing average n-type and p-type doping levels reduces resistance including active resistance (see FIG. 5A), that average n-type and p-type doping levels may be selected based on operating current to minimize junction capacitance (see FIG. 5B), and that increasing average n-type and p-type doping levels reduces the operating voltage (see left axis of FIGS. 5C and 5D) of a given laser. However, the right axis of FIGS. 5C and 5D also demonstrate that increasing average p-type doping levels may reduce the optical power of a given laser.

Although FIGS. 5A, 5B, 5C, and 5D demonstrate the ability to adjust average doping levels and/or average dopant densities in one or more regions of a laser to reduce active resistance and active capacitance of the laser, one of ordinary skill in the art in view of the present disclosure would appreciate that doping levels and/or dopant densities in a portion of a region of a laser may be adjusted to reduce active resistance and active capacitance of the laser. For example, rather than adjusting doping levels and/or dopant densities in an entire mirror region, doping levels and/or dopant densities in a portion of a mirror region (e.g., a subset of mirror layers, a single mirror layer, and/or the like) may be adjusted to reduce active resistance and active capacitance of the laser. In this regard, one of ordinary skill in the art in view of the present disclosure would appreciate that a region of a laser may refer to a portion of a layer structure of a laser (e.g., an entire mirror), a subset of a portion of a layer structure of a laser (e.g., less than an entire mirror, a plurality of mirror layers, and/or the like), and/or a component of a portion of a layer structure of a laser (e.g., a single mirror layer). Furthermore, for lasers that are not VCSELs, a region of a laser may similarly refer to a portion of a structure of the laser, a subset of a portion of a structure of a laser, and/or a component of a portion of a layer structure of a laser.

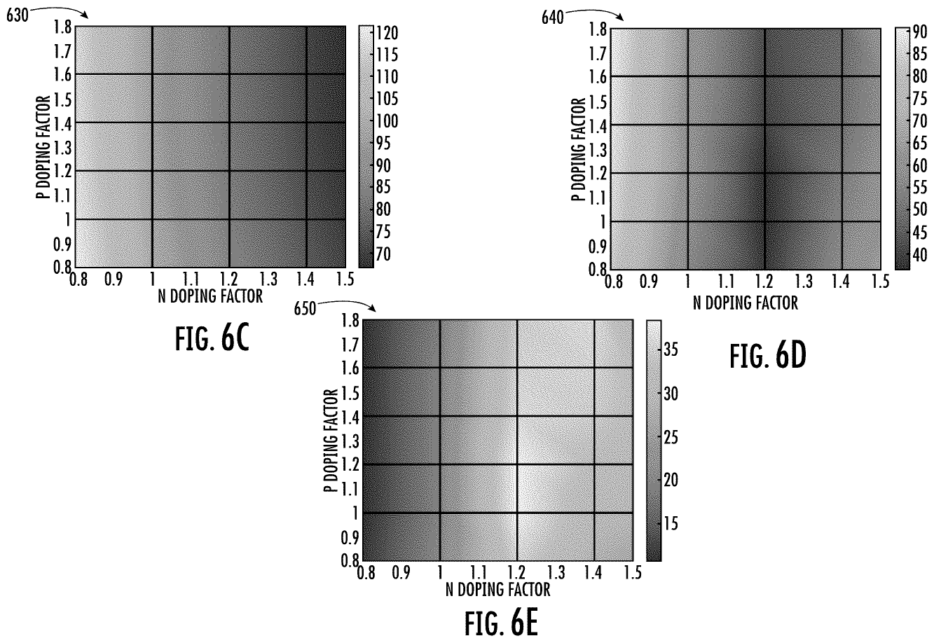

FIG. 6A is a density map 610 illustrating the junction capacitance minimum values of lasers having various doping levels in mirror regions, in accordance with embodiments of the invention. In FIG. 6A, lighter shading corresponds to higher junction capacitance minimum values in femtofarads, and darker shading corresponds to lower junction capacitance minimum values in femtofarads.

FIG. 6B is another density map 620 illustrating the current at which the junction capacitance minimum values of the lasers of FIG. 6A occur, in accordance with embodiments of the invention. In FIG. 6B, lighter shading corresponds to higher currents in milliamps, and darker shading corresponds to lower currents in milliamps.

As shown in FIGS. 6A and 6B, the vertical axis identifies a doping factor for a p-type doped mirror region, and the horizontal axis identifies a doping factor for an n-type doped mirror region. In this regard, on the two density maps 610 and 620, the values graphed at an n-type doping factor of 1 and a p-type doping factor of 1 correspond to a conventional VCSEL for emitting light having a wavelength of 980 nanometers having an n-type doped mirror region and a p-type doped mirror region without an enhanced parasitic response. The other points on the two density maps 610 and 620 with doping factors greater than 1 correspond to similar VCSELs with an increase in the average n-type doping levels and the average p-type doping levels in the mirror regions. For example, the value graphed at an n-type doping factor of 1.2 and a p-type doping factor of 1.4 corresponds to a VCSEL in which the average n-type doping level is 1.2 times greater than that of the conventional VCSEL and the average p-type doping level is 1.4 times greater than that of the conventional VCSEL.

FIG. 6C is another density map 630 illustrating the resistance of lasers having various doping levels in mirror regions, in accordance with embodiments of the invention. In particular, the density map 630 illustrates the resistance of the lasers of FIGS. 6A and 6B at a current of 7.5 milliamps as a function of the p-type doping factor and the n-type doping factor. In FIG. 6C, lighter shading corresponds to higher resistance values in Ohms, and darker shading corresponds to lower resistance values in Ohms.

FIG. 6D is another density map 640 illustrating the active capacitance of lasers having various doping levels in mirror regions, in accordance with embodiments of the invention. The density map 640 illustrates the active capacitance (including mesa capacitance as described above with respect to FIG. 2) of the lasers of FIGS. 6A and 6B at a current of 7.5 milliamps as a function of the p-type doping factor and the n-type doping factor. In FIG. 6D, lighter shading corresponds to higher capacitance values in femtofarads, and darker shading corresponds to lower capacitance values in femtofarads.

As will be appreciated by one of ordinary skill in the art in view of the present disclosure, the electrical circuit model 150 as described herein with respect to FIG. 2 and the density maps 610-640 of FIGS. 6A-6D may be used to evaluate parasitic responses and total responses of lasers having various combinations of p-type doping factors and n-type doping factors. In this regard, FIG. 6E is a density map 650 illustrating the −3 dB frequency of parasitic transfer functions at an operating current of 7.5 milliamps of lasers having various doping levels in mirror regions, in accordance with embodiments of the invention. In FIG. 6E, lighter shading corresponds to higher −3 dB frequencies in gigahertz, and darker shading corresponds to lower −3 dB frequencies in gigahertz. As shown in FIG. 6E, the maximum bandwidth of the parasitic response, which corresponds to the highest −3 dB frequency, at an operating current of 7.5 milliamps is achieved for this exemplary laser with a p-type doping factor of 1.2 and an n-type doping factor of 1.2.

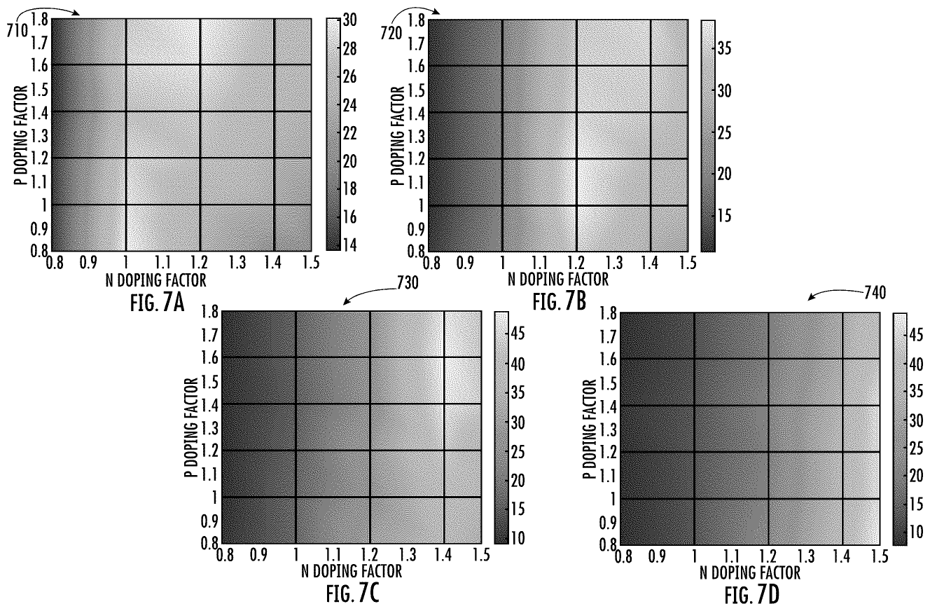

FIGS. 7A-7D are density maps 710-740 illustrating the −3 dB frequency of parasitic transfer functions at different operating currents of lasers having various doping levels in mirror regions, in accordance with embodiments of the invention. In particular, the lasers correspond to those of FIGS. 6A-6B. As such, the values graphed at an n-type doping factor of 1 and a p-type doping factor of 1 correspond to a conventional VCSEL for emitting light having a wavelength of 980 nanometers having an n-type doped mirror region and a p-type doped mirror region without an optimized parasitic transfer function. The other points on the density maps 710-740 with doping factors greater than 1 correspond to similar VCSELs with an increase in the average n-type doping levels and the average p-type doping levels in the mirror regions.

As noted, each of the density maps 710-740 illustrates the −3 dB frequency of parasitic transfer functions at different operating currents. In particular, the density maps 710-740 correspond to operating currents of 6.0 milliamps, 7.5 milliamps, 9.0 milliamps, and 11.0 milliamps, respectively. Given that the active resistance and active capacitance of a laser depend on the operating current, the doping levels in the mirror regions may be optimized based on a given operating current. For example, and as shown in the density map 710 of FIG. 7A, the maximum bandwidth of the parasitic response, which corresponds to the highest −3 dB frequency, at an operating current of 6.0 milliamps is achieved for this exemplary laser with a p-type doping factor of 1.8 and an n-type doping factor of 1.2. The density map 720 of FIG. 7B is the same as the density map 650 of FIG. 6E and therefore also shows the maximum bandwidth of the parasitic response at an operating current of 7.5 milliamps is achieved with a p-type doping factor of 1.2 and an n-type doping factor of 1.2. As shown in the density map 730 of FIG. 7C, the maximum bandwidth of the parasitic response at an operating current of 9.0 milliamps is achieved for this exemplary laser with a p-type doping factor of 1.6 and an n-type doping factor of 1.4. Finally, as shown in the density map 740 of FIG. 7D, the maximum bandwidth of the parasitic response at an operating current of 11.0 milliamps is achieved for this exemplary laser with a p-type doping factor of 0.8 and an n-type doping factor of 1.5.

As will be appreciated by one of ordinary skill in the art in view of the present disclosure, the electrical circuit model 150 of FIG. 2 and the techniques used to generate the density maps 610-640 of FIGS. 6A-6D and the density maps 710-740 of FIGS. 7A-7D may be utilized to select average dopant densities to optimize a parasitic transfer function of a laser by (i) decreasing the active resistance and (ii) decreasing the active capacitance of the laser. Furthermore, by optimizing the parasitic transfer function of the laser, the total response and associated maximum bandwidth of the laser may be improved.

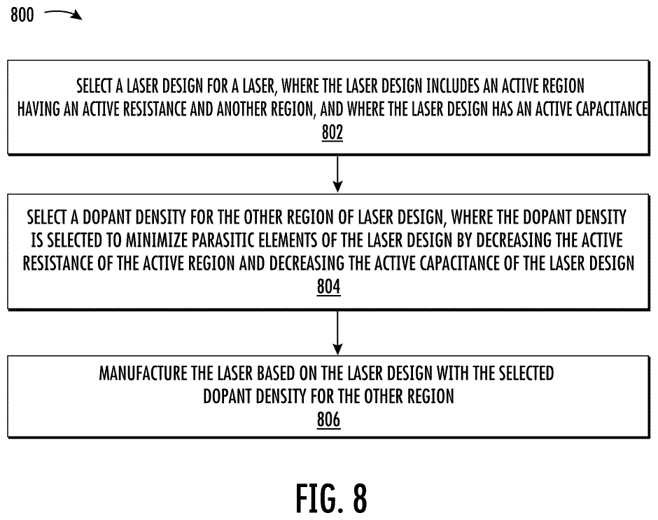

FIG. 8 illustrates a method 800 for manufacturing a laser, in accordance with an embodiment of the invention. As shown in block 802, the method 800 may include selecting a laser design for a laser, where the laser design includes an active region having an active resistance and another region, and where the laser design has an active capacitance. For example, the method 800 may include selecting a VCSEL design, where the VCSEL design includes an active region, a first mirror region, and a second mirror region, where the active region is positioned between the first mirror region and the second mirror region.

As shown in block 804, the method 800 may include selecting a dopant density for the other region of laser design, where the dopant density is selected to minimize parasitic elements of the laser design by decreasing the active resistance of the active region and decreasing the active capacitance of the laser design. For example, in a VCSEL design, the method 800 may include selecting a first dopant density for the first mirror region and/or a portion of the first mirror region (e.g., one or more mirror layers) and selecting a second dopant density for the second mirror region and/or a portion of the second mirror region (e.g., one or more mirror layers). In such an example, the first dopant density and the second dopant density may be selected to minimize the parasitic elements of the laser design by decreasing the active resistance of the active region and decreasing the active capacitance of the laser design.

In some embodiments, the method 800 may include selecting the dopant density for the other region to increase a −3 dB frequency of a parasitic transfer function of the laser at a particular wavelength by at least 30%, such as by 50%, 100%, 150%, 200%, 300%, or even 400% (e.g., as compared to a −3 dB frequency of a parasitic transfer function of a similar laser without an enhanced parasitic transfer function). Additionally, or alternatively, the method 800 may include selecting the dopant density to achieve a −3 dB frequency of a parasitic transfer function of the laser of at least 40 GHz at an operating wavelength of the laser.

Additionally, or alternatively, the method 800 may include selecting the dopant density for the other region to obtain an active resistance of between about 45 ohms and 75 ohms at an operating bias of the laser. In some embodiments, the method 800 may include selecting the dopant density for the other region to obtain an active capacitance of less than about 60 femtofarads at an operating bias of the laser. For example, the dopant density may be selected to obtain an active resistance of less than about 100 ohms and an active capacitance of less than about 60 femtofarads at an operating bias of the laser. As another example, the dopant density may be selected to obtain an active resistance of less than about 90 ohms and an active capacitance of less than about 50 femtofarads at an operating bias of the laser.

As shown in block 806, the method 800 may include manufacturing the laser based on the laser design with the selected dopant density for the other region. For example, the method 800 may include forming a plurality of epitaxial layers to form the active region and/or the other region. As another example, the method 800 may include doping the other region to achieve the selected dopant density.

In some embodiments, the method 800 may include selecting a doping profile for the other region, where the doping profile is selected to optimize performance of the laser. For example, the method 800 may include selecting the doping profile to optimize an intrinsic response of the laser. As another example, the method 800 may include selecting the doping profile to optimize a bandwidth at which the laser is capable of operating at a particular wavelength.

In some embodiments, the method 800 may include providing an oxide aperture in the laser. For example, one or more layers of a mirror region may be selectively oxidized to form the oxide aperture.

As described herein with respect to FIG. 2, the active capacitance Cₐ of a laser may include a junction capacitance Cⱼ in parallel with a mesa capacitance Cₘₑₛₐ. The junction capacitance Cⱼ may include a depletion capacitance and a diffusion capacitance, and the mesa capacitance Cₘₑₛₐ may include an oxide capacitance (ox in series with an intrinsic capacitance Cᵢₙₜ associated with an intrinsic region below the oxide aperture, such as in an un-depleted area of the active region. In some embodiments, the method 800 may include selecting the dopant density for the other region to optimize the parasitic response of the laser by decreasing the diffusion capacitance.

Method 800 may include additional embodiments, such as any single embodiment or any combination of embodiments described herein. Although FIG. 8 shows example blocks of method 800, in some embodiments, method 800 may include additional blocks, fewer blocks, different blocks, or differently arranged blocks than those depicted in FIG. 8. Additionally, or alternatively, two or more of the blocks of method 800 may be performed in parallel.

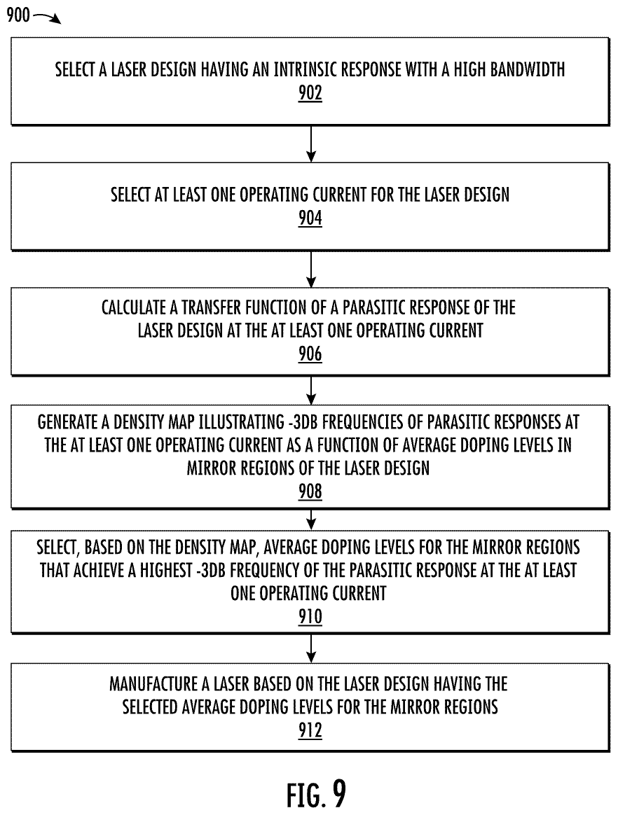

FIG. 9 illustrates another method 900 for manufacturing a laser, in accordance with an embodiment of the invention. As shown in block 902, the method 900 may include selecting a laser design having an intrinsic response with a high bandwidth (e.g., at least 20 GHz, at least 30 GHz, at least 40 GHz, and/or the like). For example, the method 900 may include selecting a laser design including an active region positioned between two mirror regions doped to increase the bandwidth of the intrinsic response.

As shown in block 904, the method 900 may include selecting at least one operating current for the laser design. For example, the method 900 may include selecting an operating current, a range of operating currents, and/or the like based on one or more other design objectives (e.g., an intended use of the laser, a target power consumption of the laser, and/or the like).

As shown in block 906, the method 900 may include calculating a transfer function of a parasitic response of the laser design at the at least one operating current. For example, the method 900 may include using the electrical circuit model 150 as described herein with respect to FIG. 2 to calculate the transfer function of the parasitic response of the laser design.

As shown in block 908, the method 900 may include generating a density map illustrating −3 dB frequencies of parasitic transfer functions at the at least one operating current as a function of average doping levels in mirror regions of the laser design. For example, the method 900 may include using the electrical circuit model 150 as described herein with respect to FIG. 2 to simulate parasitic responses and generate one or more density maps similar to those described herein with respect to FIGS. 6E and 7A-7D.

As shown in block 910, the method 900 may include selecting, based on the density map, average doping levels for the mirror regions that achieve a highest −3 dB frequency of the parasitic transfer function at the at least one operating current. Using the density map 650 of FIG. 6E as an example, the method 900 may include selecting a p-type doping factor of 1.2 and an n-type doping factor of 1.2 for mirror regions of the laser design and applying the doping factors to the original average doping levels of the laser design because the density map 650 indicates that such doping levels achieve a maximum bandwidth of the parasitic response at an operating current of 7.5 milliamps.

As shown in block 912, the method 900 may include manufacturing the laser based on the laser design having the selected average doping levels for the mirror regions. For example, the method 900 may include depositing one or more epitaxial layers to form the mirror regions and doping the one or more epitaxial layers to achieve the selected average doping levels.

Method 900 may include additional embodiments, such as any single embodiment or any combination of embodiments described herein. Although FIG. 9 shows example blocks of method 900, in some embodiments, method 900 may include additional blocks, fewer blocks, different blocks, or differently arranged blocks than those depicted in FIG. 9. Additionally, or alternatively, two or more of the blocks of method 900 may be performed in parallel.

As noted, even for lasers with an optimized parasitic transfer function, the total transfer function of the laser may not have a high enough bandwidth to meet the demands for high-speed and high-volume data communication. Some embodiments of the present invention are directed to a laser having an optimized parasitic transfer function and for which the bandwidth of the intrinsic transfer function of the laser is increased by increasing strain in the active region. Again, increasing strain in the laser may involve a shift of the operating wavelength to lower frequencies that causes an increase in the cavity length of the laser, which reduces the bandwidth of the parasitic transfer function and the total transfer function of the laser. In this regard, some embodiments of the present invention balance the increase in the bandwidth of the intrinsic transfer function caused by increasing the cavity length with the reduction in the bandwidth of the parasitic transfer function as a result of the increased cavity length.

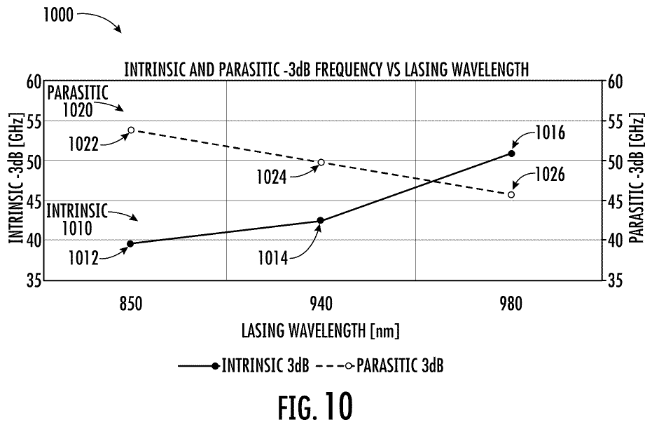

FIG. 10 is a graph illustrating the intrinsic −3 dB frequencies 1010 and the parasitic −3 dB frequencies 1020 of three lasers as a function of operating wavelength, in accordance with an embodiment of the invention. In particular, the lasers of FIG. 10 are VCSELs having optimized parasitic transfer functions using one or more of the methods, techniques, and/or designs described herein with respect to FIGS. 1-9. For example, the VCSELs may correspond to VCSELs having mirror regions with average dopant densities that have been selected to optimize the −3 dB frequency of the parasitic transfer functions of the VCSELs.

In FIG. 10, data points 1012 and 1022 respectively correspond to the −3 dB frequencies of an intrinsic transfer function and a parasitic transfer function of a first VCSEL having an operating wavelength of 850 nanometers. Data points 1014 and 1024 respectively correspond to the −3 dB frequencies of an intrinsic transfer function and a parasitic transfer function of a second VCSEL having an operating wavelength of 940 nanometers. Finally, data points 1016 and 1026 respectively correspond to the −3 dB frequencies of an intrinsic transfer function and a parasitic transfer function of a third VCSEL having an operating wavelength of 980 nanometers. The second and third VCSELs have higher operating wavelengths as compared to the first VCSEL due to increased strain and increased cavity lengths. For example, the increased strain may be achieved by increasing indium concentrations in InGaAs/AlGaAs quantum wells of the active regions of the second and third VCSELs.

As shown in FIG. 10, the increased strain and cavity length of the second VCSEL results in an increase in the −3 dB frequency of the intrinsic transfer function as shown by a comparison of data points 1012 and 1014. However, the increased strain and cavity length in the second VCSEL also decreased the −3 dB frequency of the parasitic transfer function as shown by a comparison of data points 1022 and 1024.

As another example, and as shown in FIG. 10, the further increased strain and cavity length of the third VCSEL results in a further increase in the −3 dB frequency of the intrinsic transfer function as shown by a comparison of data points 1014 and 1016. However, the increased strain and cavity length in the third VCSEL also decreased the −3 dB frequency of the parasitic transfer function as shown by a comparison of data points 1024 and 1026.

In FIG. 10, the vertical axis scale for the intrinsic −3 dB frequencies 1010 does not correspond to the vertical axis scale for the parasitic −3 dB frequencies 1020. However, FIG. 10 demonstrates that increasing strain and cavity length of a laser having an already optimized parasitic transfer function involves a bandwidth tradeoff between the intrinsic transfer function and the parasitic transfer function. In this regard, embodiments of the present invention include a laser that is configured to operate at an operating wavelength selected to maximize a total response of the laser in view of this bandwidth tradeoff. For example, a laser may be configured to operate at a wavelength at which further increasing its strain and cavity length would yield an increase in bandwidth of the intrinsic transfer function that is equal to a resulting decrease in bandwidth of the parasitic transfer function. In some embodiments, the laser may be configured to operate at an operating wavelength selected to maximize a total response of the laser by providing a cavity defining a cavity length that is half the operating wavelength.

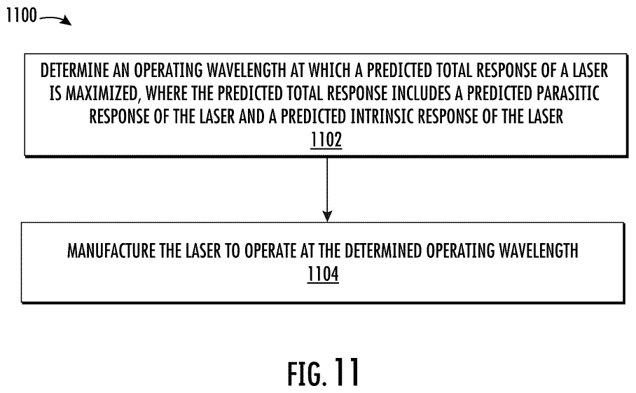

FIG. 11 illustrates another method 1100 for manufacturing a laser, in accordance with an embodiment of the invention. As shown in block 1102, the method 1100 may include determining an operating wavelength at which a predicted total response of the laser is maximized, where the predicted total response includes a predicted parasitic response of the laser and a predicted intrinsic response of the laser. For example, the method may include performing one or more of the steps described herein with respect to FIGS. 8, 9, and/or 12 to determine an operating wavelength at which the predicted total response of the laser is maximized.

Additionally, or alternatively, the method 1100 may include determining a parasitic −3 dB frequency of a predicted parasitic transfer function of the predicted parasitic response at a plurality of wavelengths and determining an intrinsic −3 dB frequency of a predicted intrinsic transfer function of the predicted intrinsic response at the plurality of wavelengths. The method may further include selecting, as the operating wavelength and from the plurality of wavelengths, a wavelength at which a combination of the parasitic −3 dB frequency and the intrinsic −3 dB frequency at the wavelength is greatest.

As shown in block 1104, the method 1100 may further include manufacturing the laser to operate at the predetermined operating wavelength. For example, the method may include providing a first mirror region (e.g., by forming a plurality of epitaxial layers), providing an active region on the first mirror region (e.g., by forming additional epitaxial layers), and providing a second mirror region on the active region (e.g., by forming another plurality of epitaxial layers), where the first mirror region, the active region, and the second mirror region are configured to define a cavity length corresponding to a multiple of half the predetermined operating wavelength. In some embodiments, the method may include selecting one or more dopant densities in the laser to optimize the predicted parasitic transfer function of the predicted parasitic response of the laser by (i) decreasing an active resistance of the laser and (ii) decreasing an active capacitance of the laser and doping portions of the laser (e.g., the first and second mirror regions) to achieve the one or more average dopant densities.

Method 1100 may include additional embodiments, such as any single embodiment or any combination of embodiments described herein. Although FIG. 11 shows example blocks of method 1100, in some embodiments, method 1100 may include additional blocks, fewer blocks, different blocks, or differently arranged blocks than those depicted in FIG. 11. Additionally, or alternatively, two or more of the blocks of method 1100 may be performed in parallel.

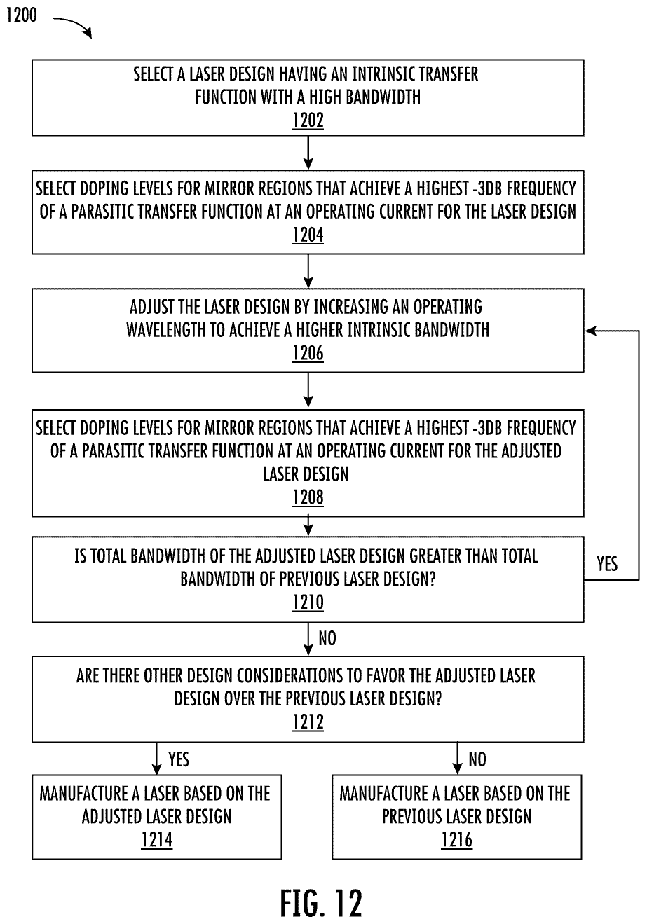

FIG. 12 illustrates a method 1200 for manufacturing a laser, in accordance with an embodiment of the invention. As shown in block 1202, the method 1200 may include selecting a laser design having an intrinsic transfer function with a high bandwidth (e.g., at least 20 GHZ, at least 30 GHZ, at least 40 GHZ, and/or the like). For example, the method 1200 may include selecting a laser design including an active region positioned between two doped mirror regions.

As shown in block 1204, the method 1200 may include selecting doping levels for mirror regions of the laser design that achieve a highest −3 dB frequency of a parasitic transfer function at an operating current for the laser design. For example, the method 1200 may include performing one or more of the steps described herein with respect to FIGS. 1-9 to determine doping levels for the mirror regions that achieve the highest −3 dB frequency of the parasitic transfer function at an operating current for the laser design.

In some embodiments, the method 1200 may include selecting at least one operating current for the laser design. For example, the method 1200 may include selecting an operating current, a range of operating currents, and/or the like based on one or more other design objectives (e.g., an intended use of the laser, a target power consumption of the laser, reliability of the laser, and/or the like).

As shown in block 1206, the method 1200 may include adjusting the laser design with the selected doping levels by increasing an operating wavelength of the laser design to achieve a higher intrinsic bandwidth. For example, the method 1200 may include adjusting the laser design to increase strain in the active region, which may increase the operating wavelength of the laser, which increases the cavity length of the laser. Additionally, adjusting the laser design in this manner may increase the bandwidth of the intrinsic transfer function of the laser design but may also decrease the bandwidth of the parasitic transfer function of the laser design.

As shown in block 1208, the method 1200 may include selecting doping levels for mirror regions that achieve a highest −3 dB frequency of a parasitic transfer function at an operating current for the adjusted laser design. For example, the method 1200 may include performing one or more of the steps described herein with respect to FIGS. 1-9 to determine doping levels for the mirror regions that achieve the highest −3 dB frequency of the parasitic transfer function at an operating current for the adjusted laser design.

As shown in block 1210, the method 1200 may include determining whether the total bandwidth of the adjusted laser design is greater than the total bandwidth of the previous laser design (e.g., the laser design before the last adjustment in block 1206). For example, the method 1200 may include determining whether the increase in intrinsic bandwidth caused a decrease in the bandwidth of the parasitic transfer function that is less than an increase in the bandwidth of the intrinsic transfer function caused by increasing the operating wavelength. In some embodiments, the method 1200 may include calculating transfer functions of the parasitic and intrinsic responses at the operating current (e.g., using the electrical circuit model 150 as described herein with respect to FIG. 1B) and determining, based on the transfer functions, bandwidths of the parasitic and intrinsic responses. The method 1200 may also include comparing the bandwidths of the parasitic and intrinsic transfer functions to the respective bandwidths of the parasitic and intrinsic transfer functions before the laser design was adjusted to increase its operating wavelength.

As shown in FIG. 12, the method 1200 may include, based on determining that the total bandwidth of the adjusted laser design is greater than the total bandwidth of the previous laser design, repeating the step shown in block 1206 of adjusting the laser design by increasing the operating wavelength. The method 1200 may include repeating the step shown in block 1208 of selecting doping levels for mirror regions that achieve a highest −3 dB frequency of a parasitic transfer function at an operating current for the adjusted laser design and the step shown in block 1210 of determining whether the total bandwidth of the adjusted laser design is greater than the total bandwidth of the previous laser design. In this regard, the method 1200 may include iteratively repeating the steps shown in blocks 1206, 1208, and 1210 until a determination is made that the total bandwidth of the adjusted laser design is not greater than the total bandwidth of the previous laser design.

As shown in block 1212, the method 1200 may include, based on determining that the total bandwidth of the adjusted laser design is not greater than the total bandwidth of the previous laser design, determining whether there are other design considerations to favor the adjusted laser design over the previous laser design. For example, even though the total bandwidth of the adjusted laser design is the same as or lower than the previous laser design, other design considerations may make the adjusted laser design preferred as compared to the previous laser design.

As shown in block 1214, the method 1200 may include, based on determining that there are other design considerations to favor the adjusted laser design over the previous laser design, manufacturing a laser based on the adjusted laser design. For example, the method 1200 may include manufacturing a laser having the selected doping levels for the mirror regions from the step of block 1208 and having an operating wavelength corresponding to the wavelength achieved by the step of block 1206.

As shown in block 1216, the method 1200 may include, based on determining that there are not other design considerations to favor the adjusted laser design over the previous laser design, manufacturing a laser based on the previous laser design. For example, the method 1200 may include manufacturing a laser having the selected doping levels for the mirror regions from the step of block 1204 and having an operating wavelength corresponding to the wavelength before the last performance of the step of block 1206.

In some embodiments, the method 1200 may include, based on determining that the decrease in the bandwidth of the parasitic transfer function is not equal to the increase in the bandwidth of the intrinsic transfer function, manufacturing a laser based on the laser design before the last adjustment. For example, the method 1200 may include determining that the last adjustment of the laser design to increase the operating wavelength (e.g., performed in the step of block 1206) resulted in a decrease in the bandwidth of the parasitic transfer function that was greater than a resulting increase in the bandwidth of the intrinsic transfer function. In other words, the method 1200 may include determining that the last adjustment to the laser design to increase the operating wavelength resulted in a net decrease in the total response of the laser design. Based on such a determination, the method 1200 may include manufacturing a laser based on a laser design immediately preceding the last adjustment to increase operating wavelength.

In some embodiments, the method 1200 may include, based on determining that the decrease in the bandwidth of the parasitic transfer function is greater than the increase in the bandwidth of the intrinsic transfer function, returning to the laser design immediately preceding the last adjustment to increase operating wavelength and increasing the operating wavelength by an amount that is less than the amount by which the operating wavelength was previously adjusted. For example, after adjusting a laser design A by increasing the operating wavelength by 40 nanometers to obtain laser design B, the method 1200 may include determining that the 40-nanomter increase resulted in a decrease in the bandwidth of the parasitic transfer function that is greater than the increase in the bandwidth of the intrinsic transfer function for laser design B. In such an example, the method 1200 may include returning to laser design A and adjusting the design by increasing the operating wavelength by 20 nanometers to obtain laser design A′. The method 1200 may further include determining whether the 20-nanometer increase resulted in a decrease in the bandwidth of the parasitic transfer function that is greater than the increase in the bandwidth of the intrinsic transfer function for laser design A′. In this way, the method 1200 may include refining the amount of increase to the operating wavelength achieved by adjusting the laser design until a decrease in the bandwidth of the parasitic transfer function corresponds to an increase in the bandwidth of the intrinsic transfer function.

Method 1200 may include additional embodiments, such as any single embodiment or any combination of embodiments described herein. Although FIG. 12 shows example blocks of method 1200, in some embodiments, method 1200 may include additional blocks, fewer blocks, different blocks, or differently arranged blocks than those depicted in FIG. 12. Additionally, or alternatively, two or more of the blocks of method 1200 may be performed in parallel.

As will be appreciated by one of ordinary skill in the art in view of this disclosure, the present invention may include and/or be embodied as an apparatus (including, for example, a photodetector, a device, and/or the like), as a method (including, for example, a manufacturing method, a computer-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention and that this invention is not to be limited to the specific constructions and arrangements shown and described, as various other changes, combinations, omissions, modifications and substitutions, in addition to those set forth in the above paragraphs, are possible. In light of this disclosure, those skilled in the art will appreciate that various adaptations, modifications, and combinations of the just described embodiments may be configured without departing from the scope and spirit of the invention. Therefore, it is to be understood that, within the scope of the appended claims, the invention may be practiced other than as specifically described herein.

What is claimed is:

1. A laser, wherein:
the laser has a total response comprising a parasitic response and an intrinsic response; and
the laser is configured to operate at an operating wavelength selected to maximize the total response of the laser.

2. The laser of claim 1, comprising a cavity defining a cavity length, wherein the cavity length determines the operating wavelength of the laser.

3. The laser of claim 2, wherein a parasitic transfer function of the parasitic response has a lower −3 dB frequency for a laser design comprising another cavity having a longer cavity length than the cavity length.

4. The laser of claim 1, wherein an intrinsic transfer function of the intrinsic response has a higher −3 dB frequency for a laser design configured to operate at a longer operating wavelength than the operating wavelength.

5. The laser of claim 2, wherein a parasitic transfer function of the parasitic response has a higher −3 dB frequency for a laser design comprising another cavity having a shorter cavity length than the cavity length.

6. The laser of claim 1, wherein an intrinsic transfer function of the intrinsic response has a lower −3 dB frequency for a laser design configured to operate at a longer operating wavelength than the operating wavelength.

7. The laser of claim 1, wherein the laser has an active resistance and an active capacitance, and wherein one or more dopant densities in the laser are selected to optimize a parasitic transfer function of the parasitic response of the laser by (i) decreasing the active resistance and (ii) decreasing the active capacitance.

8. A laser, comprising:
a first mirror region;
a second mirror region; and
an active region positioned between the first mirror region and the second mirror region, wherein the active region comprises a cavity defining a cavity length, and wherein the cavity length is a multiple of half an operating wavelength;
wherein the laser has a total response comprising a parasitic response and an intrinsic response;
wherein the laser is configured to operate at the operating wavelength; and
wherein the operating wavelength is selected to maximize the total response of the laser.

9. The laser of claim 8, wherein:
the first mirror region comprises a first dopant at a first dopant density;
the second mirror region comprises a second dopant at a second dopant density;
the active region has an active resistance;
the laser has an active capacitance; and
the first dopant density and the second dopant density are selected to optimize a parasitic transfer function of the parasitic response of the laser by (i) decreasing the active resistance of the active region and (ii) decreasing the active capacitance of the laser.

10. The laser of claim 9, wherein the first dopant density and the second dopant density are selected to obtain an active resistance of between about 50 ohms and 70 ohms at an operating bias of the laser.

11. The laser of claim 9, wherein the active resistance is less than about 90 ohms at an operating bias of the laser, and wherein the active capacitance is less than about 50 femtofarads at the operating bias of the laser.

12. The laser of claim 8, wherein:
the first mirror region has a first thickness and a first doping profile of a first dopant through the first thickness of the first mirror region;
the second mirror region has a second thickness and a second doping profile of a second dopant through the second thickness of the second mirror region; and
the first doping profile and the second doping profile are selected to optimize a bandwidth at which the laser is capable of operating at the operating wavelength.

13. The laser of claim 8, wherein the first mirror region comprises a first distributed Bragg reflector, and wherein the second mirror region comprises a second distributed Bragg reflector.

14. The laser of claim 8, wherein the active region is undoped.

15. The laser of claim 8, comprising an aperture, wherein the active region comprises a depleted junction under the aperture.

16. The laser of claim 8, wherein the laser is a vertical-cavity surface-emitting laser.

17. A method of manufacturing a laser, the method comprising:
determining an operating wavelength at which a predicted total response of the laser is maximized, wherein the predicted total response comprises a predicted parasitic response of the laser and a predicted intrinsic response of the laser; and
manufacturing the laser to operate at the determined operating wavelength.

18. The method of claim 17, wherein manufacturing the laser comprises providing a cavity defining a cavity length, wherein the cavity length is half the determined operating wavelength.

19. The method of claim 17, wherein determining the operating wavelength at which the predicted total response of the laser is maximized comprises:
determining a parasitic −3 dB frequency of a predicted parasitic transfer function of the predicted parasitic response at a plurality of wavelengths;
determining an intrinsic −3 dB frequency of a predicted intrinsic transfer function of the predicted intrinsic response at the plurality of wavelengths; and
selecting, as the operating wavelength and from the plurality of wavelengths, a wavelength at which a combination of the parasitic −3 dB frequency and the intrinsic −3 dB frequency at the wavelength is greatest.

20. The method of claim 17, wherein manufacturing the laser comprises:
selecting one or more dopant densities in the laser to optimize a predicted parasitic transfer function of the predicted parasitic response of the laser by (i) decreasing an active resistance of the laser and (ii) decreasing an active capacitance of the laser; and
doping portions of the laser to achieve the one or more dopant densities.
